(19) United States
(12) Patent Application Publication
(10) Pub. No.: US 2020/0411731 A1
(43) Pub. Date: Dec. 31, 2020

(54) EPITAXY WAVELENGTH CONVERSION ELEMENT, LIGHT-EMITTING SEMICONDUCTOR COMPONENT, AND METHODS FOR PRODUCING THE EPITAXY WAVELENGTH CONVERSION ELEMENT AND THE LIGHT-EMITTING SEMICONDUCTOR COMPONENT

(71) Applicant: OSRAM OLED GmbH, Regensburg (DE)

(72) Inventors: Alexander TONKIKH, Wenzenbach (DE); Tansen VARGHESE, Regensburg (DE); Martin Rudolf BEHRINGER, Regensburg (DE)

(21) Appl. No.: 16/757,274

(22) PCT Filed: Oct. 18, 2018
(86) PCT No.: PCT/EP2018/078535

§ 371 Date: Apr. 17, 2020

(30) Foreign Application Priority Data
Oct. 20, 2017 (DE) 10 2017 124 559.6

(51) Int. Cl. H01L 33/50; H01L 33/28; H01L 33/00; H01L 33/30; H01L 33/22

(52) U.S. Cl. CPC H01L 33/502; H01L 33/28; H01L 33/0062; H01L 2933/0041; H01L 33/505; H01L 33/30; H01L 33/22; H01L 33/0083

(57) ABSTRACT

An epitaxial wavelength conversion element (100) is specified which comprises a semiconductor layer sequence (1) with an active layer (10) arranged between a first cladding layer (11) and a second cladding layer (12), the active layer being embodied to absorb light in a first wavelength range and to re-emit light in a second wavelength range, which is different from the first wavelength range, wherein the first cladding layer and the active layer are based on a III-V compound semiconductor material system and wherein the second cladding layer is based on a II-VI compound semiconductor material system.

Furthermore, a light-emitting semiconductor device comprising a light-emitting semiconductor chip and an epitaxial wavelength conversion element and methods for manufacturing the epitaxial wavelength conversion element and the light-emitting semiconductor device are specified.

An epitaxial wavelength conversion element, a light-emitting semiconductor device, and methods for manufacturing the epitaxial wavelength conversion element and the light-emitting semiconductor device are specified.

This patent application claims the priority of the German patent application 10 2017 124 559.6, the disclosure content of which is hereby included by reference.

Wavelength converters made of semiconductor materials are known, which absorb excitation light of one wavelength in an active layer using photoluminescence and emit light of another wavelength. In particular, the excitation light generates charge carrier pairs in the active layer, which recombine possibly again under light emission. However, it is also possible that such a wavelength converter has a semiconductor material in another layer which can also absorb excitation light and thus generate charge carrier pairs, which, however, are trapped at surfaces or interfaces and recombine there non-radiatively. Excitation light for photoluminescence is thus lost, which reduces the efficiency of the wavelength converter.

At least one object of certain embodiments is to specify an epitaxial wavelength conversion element. At least one further object of certain embodiments is to specify a light-emitting semiconductor device with an epitaxial wavelength conversion element. Further objects of certain embodiments are to specify methods for their manufacture.

These objects are achieved by subject-matters and methods according to the independent claims. Advantageous embodiments and developments of the method and the subject-matter are characterized in the dependent claims, and are also disclosed by the following description and the drawings.

According to at least one embodiment, an epitaxial wavelength conversion element comprises a semiconductor layer sequence with an active layer intended and embodied to absorb light in a first wavelength range and to re-emit light in a second wavelength range different from the first wavelength range.

According to at least one further embodiment, such an epitaxial wavelength conversion element is manufactured. The epitaxial wavelength conversion element can be manufactured in particular by an epitaxial process, i.e., by epitaxial growth of one or more semiconductor layers, and thus a semiconductor layer sequence, on a growth substrate. Suitable epitaxy methods can be, for example, metal organic vapor phase epitaxy (MOVPE) or molecular beam epitaxy (MBE).

According to at least one further embodiment, a light-emitting semiconductor device comprises such an epitaxial wavelength conversion element.

According to at least one further embodiment, a light-emitting semiconductor device is manufactured with such an epitaxial wavelength conversion element.

The embodiments and features described before and in the following equally relate to the epitaxial wavelength conversion element, the method for manufacturing the epitaxial wavelength conversion element, the light-emitting semiconductor device and the method for manufacturing the light-emitting semiconductor device.

The generation of light by the epitaxial wavelength conversion element is based on photoluminescence. Accordingly, the epitaxial wavelength conversion element comprises a semiconductor layer sequence with a photoluminescent active layer in which photons are generated by excitation and recombination of charge carriers, in particular electron-hole pairs. Here, excitation takes place by irradiation of excitation light in the form of light in a first wavelength range, which can be absorbed in the semiconductor layer sequence and especially in the active layer. The excitation light can be irradiated by an external pump light source such as a light-emitting semiconductor chip. Since photons are usually absorbed that have a higher energy than the photons produced by recombination in the active layer, the active region emits light converted by recombination in the second wavelength range, which is different from the first wavelength range. The epitaxial wavelength conversion element can also be simply denoted as wavelength conversion element in the following.

The semiconductor layer sequence can also comprise several active layers instead of the one active layer described here and in the following. The active layer can, for example, have a conventional pn junction, a double heterostructure, a single quantum well structure (SQW structure) or a multiple quantum well structure (MQW structure) and thus one or a plurality of suitable functional semiconductor layers.

Furthermore, the semiconductor layer sequence has at least a first and a second cladding layer, between which the active layer is arranged. Here and in the following, cladding layers are particularly such semiconductor layers which are arranged in the semiconductor layer sequence on both sides of the active layer in the growth direction and which form an confinement region for charge carriers. Accordingly, the cladding layers can also be described as charge carrier barrier layers or confinement layers. In particular, the cladding layers comprise a larger band gap than the active layer in between. The cladding layers are particularly necessary to prevent charge carrier recombination outside the active layer, for example on surfaces.

The active layer can be based on a III-V compound semiconductor material system, in particular a phosphide and/or arsenide compound semiconductor material system, i.e., InₓAl_{y}Ga_{1-x-y}P and/or InₓAl_{y}Ga_{1-x-y}As, in each case with 0≤x≤1, 0≤y≤1 and x+y≤1. In particular, the semiconductor layer sequence can comprise or consist of at least one semiconductor layer or a plurality of semiconductor layers based on such a material. The phosphide compound semiconductor material system and the arsenide compound semiconductor material system can be briefly referred to as InAlGaP and InAlGaAs. A semiconductor layer sequence which has at least one active layer based on InGaAlP can, if appropriately excited, emit light with one or more spectral components in a green to red wavelength range. A semiconductor layer sequence which has at least one active layer based on InAlGaAs can, when appropriately excited, emit light with one or more spectral components in a red to infrared wavelength range.

The semiconductor layer sequence is grown epitaxially on a growth substrate. As substrate materials semiconductor materials such as GaAs in particular or GaP, GaSb, Ge or Si can be suitable. On a GaAs substrate, both InAlGaP and InAlGaAs layers can be grown lattice-matched. For the manufacture of the epitaxial wavelength conversion element, particularly the first cladding layer can be grown on the growth substrate. Afterwards the active layer can be grown. Again afterwards the second cladding layer can be grown. In addition, it may also be possible that the growth substrate is detached after the semiconductor layer sequence has been grown. This can be advantageous, for example, in the case of a GaAs growth substrate, since GaAs can be opaque to the light in the second wavelength range generated in the active layer.

According to a further embodiment, the first cladding layer, like the active layer, is based on a previously mentioned III-V compound semiconductor material system. A variation of the band gaps of the first cladding layer and the active layer can be achieved by a variation of the respective phosphide and/or arsenide compound semiconductor material. In particular, the ratio of Ga atoms to Al atoms can lead to a variation of the band gap with small variations of the lattice parameters. Particularly preferred, the first cladding layer has a higher aluminum content than the active layer. For example, while the active layer may comprise InAlGaP with a band gap of about 1.9 eV or more, the first cladding layer may comprise InAlP with a band gap of about 2.36 eV. In principle, corresponding band gap variations are also possible when the active layer contains AlGaAs and the first cladding layer contains AlGaAs with a different composition.

According to a further embodiment, the second cladding layer is based on a II-VI compound semiconductor material system. A II-VI compound semiconductor material can comprise at least one element from the second main group, for example selected from Be, Mg, Ca, Sr, Zn and Cd, and at least one element from the sixth main group, for example selected from O, S, Se and Te. In particular, the II-VI compound semiconductor material system comprises a binary, ternary or quaternary compound containing one or more of these elements. Particularly preferably, the second cladding layer can comprise one or more Group II elements selected from Mg and Zn and one or more Group VI elements selected from S and Se. Accordingly, particularly preferably materials for the second cladding layer can be ZnSe, ZnSSe and ZnMgSSe.

The choice of the II-VI compound semiconductor material for the second cladding layer depends on the energy of the excitation photons, since the second semiconductor layer should preferably be transparent for the light in the first wavelength range that excites the active layer. This allows the wavelength conversion element to be used in such a way that the excitation light in the first wavelength range is irradiated into the active layer through the second cladding layer and the light generated in the active layer in the second wavelength range is irradiated through the first cladding layer. In particular, by using the II-VI compound semiconductor material for the second cladding layer, the second cladding layer can have a material that would have a larger bandgap than a III-V compound semiconductor material, thereby reducing the absorption of excitation light in the second cladding layer. Furthermore, the choice of material for the second cladding layer depends on the condition that the second cladding layer is grown on the active layer in a way that is as lattice-matched as possible. For example, in the case of green excitation light with a wavelength of 525 nm, the second cladding layer can comprise or be made of ZnSe with a band gap of 2.71 eV. A perfectly lattice-matched material can also be ZnS_{0.08}Se_{0.92} with a band gap of greater than or equal to 2.71 eV. In the case of blue excitation light with a wavelength of 450 nm, the material of the second cladding layer can preferably be ZnMgSSe with a band gap of greater than or equal to 2.9 eV. Alternatively, tension-stressed ZnSₓSe₁₋ₓ can be used as material for the second cladding layer. Alternatively, other materials can be used that are transparent to the excitation light in the first wavelength range and form an interface with the active layer that has a lower non-radiative recombination rate for charge carrier pairs than the corresponding radiative recombination rate of the active layer.

In particular, the second cladding layer can be grown as the final layer of the semiconductor layer sequence and accordingly form a window layer of the semiconductor layer sequence. In particular, the second cladding layer can be the only layer of the semiconductor layer sequence, i.e., the only layer of all layers grown on the growth substrate, that is based on a II-VI compound semiconductor material system, so that the II-VI compound semiconductor material is grown after the III-V compound semiconductor material. This can help to avoid contamination between the II-VI compound semiconductor material of the second cladding layer and the III-V compound semiconductor material of the other layers of the semiconductor layer sequence.

Preferably, the first cladding layer or the second cladding layer are directly adjacent to the active layer. Preferably, the first and the second cladding layer are directly adjacent to the active layer. Furthermore, it can also be possible that the semiconductor layer sequence between the active layer and the second cladding layer has a third cladding layer which, like the active layer, is based on a III-V compound semiconductor material system. The first and the third cladding layer can comprise or be made of the same material. The third cladding layer can preferably be thin and have a thickness of equal to or greater than 5 nm and equal to or less than 100 nm.

According to a further embodiment, the light-emitting semiconductor device comprises a light-emitting semiconductor chip with a light-outcoupling surface. The light-emitting semiconductor chip can be any light-emitting diode chip which, in operation, emits light in the first wavelength range via the light-outcoupling surface, which is an excitation light for the epitaxial wavelength conversion element. The epitaxial wavelength conversion element is arranged in particular with the second cladding layer on the light-outcoupling surface.

For manufacturing the light-emitting semiconductor device, the light-emitting semiconductor chip can be provided and the epitaxial wavelength conversion element can be manufactured according to the method described above, wherein, after the second cladding layer has been grown, the wavelength conversion element is mounted on the light-outcoupling surface of the light-emitting semiconductor chip with the second cladding layer, so that the first cladding layer is arranged on the side of the active layer of the wavelength conversion element opposite to the light-emitting semiconductor chip. The growth substrate can then be removed. Connecting the wavelength conversion element with the light-emitting semiconductor chip can be carried out especially in a wafer-compound. After removing the growth substrate, the wafer compound can be separated into a multitude of light-emitting semiconductor devices, each with a light-emitting semiconductor chip and an epitaxial wavelength conversion element.

Between the light-outcoupling surface and the second cladding layer a connection layer can be arranged to connect the light-emitting semiconductor chip with the wavelength conversion element. In particular, the connection layer can include a dielectric material, for example an organic connection material such as BCB (benzocyclobutene) or an inorganic connection material such as an oxide or oxynitride. In the latter case, SiON can be the preferred connection material. As an alternative to using a connection layer, the second cladding layer can also be arranged and mounted directly on the light-outcoupling surface, i.e., without a connection layer. This can be done by a direct wafer bonding process.

According to a further embodiment, the first cladding layer has a roughening on the side facing away from the active layer. In the light-emitting semiconductor device described above, the epitaxial wavelength conversion element can thus comprise a roughening on the side facing away from the light-emitting semiconductor chip. The roughening, which can be provided to improve light extraction from the wavelength conversion element, can, for example, have a structure size of greater than or equal to 200 nm and less than or equal to 1 μm and, particularly preferably, of greater than or equal to 500 nm and less than or equal to 700 nm.

Further advantages, advantageous embodiments and further developments are revealed by the embodiments described below in connection with the figures, in which:

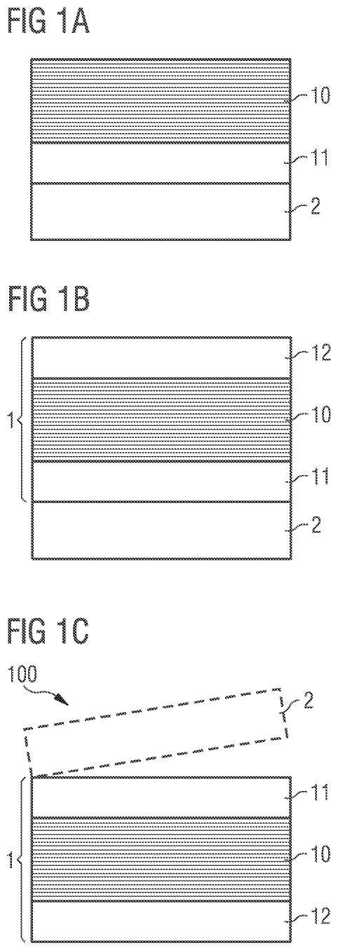

FIGS. 1A to 1C show schematic illustrations of method steps of a method for manufacturing an epitaxial wavelength conversion element according to an embodiment,

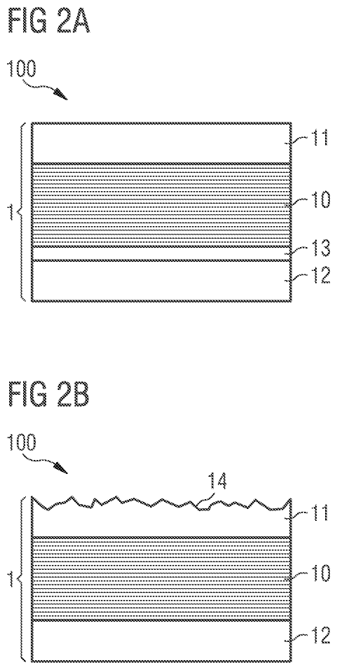

FIGS. 2A and 2B show schematic illustrations of epitaxial wavelength conversion elements according to further embodiments,

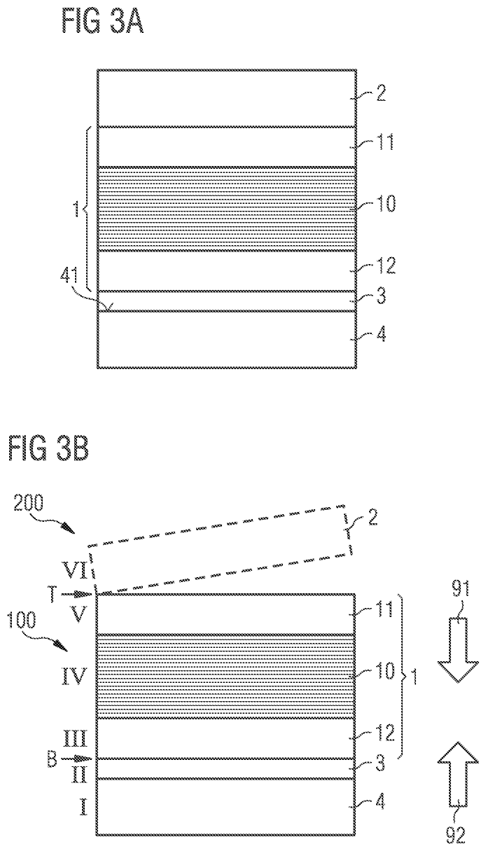

FIGS. 3A to 3C show schematic illustrations of method steps of a method for manufacturing a light-emitting device and an illustrated band diagram according to a further embodiment, and

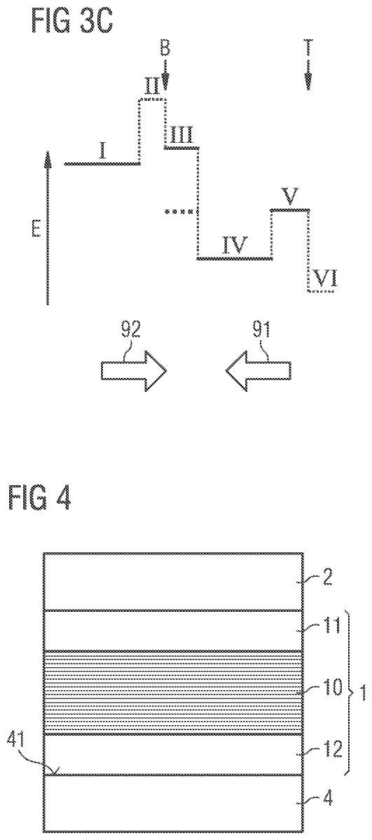

FIG. 4 show schematic illustrations of a method step of a method for manufacturing a light-emitting semiconductor device according to a further embodiment.

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

FIGS. 1A to 1C show an embodiment of a method for manufacturing an epitaxial wavelength conversion element 100. For this purpose, as shown in FIG. 1A, a growth substrate 2 is provided on which semiconductor layers based on a III-V compound semiconductor material system are epitaxially grown to form a semiconductor layer sequence 1 as shown in FIG. 1B. The process described below can in particular be carried out on a wafer basis. As growth substrate 2, a substrate wafer can be provided on which the semiconductor layer sequence 1 is grown over a large area. A plurality of wavelength conversion elements 100 can be generated by a final singulation.

In the embodiment shown, the growth substrate 2 is a GaAs substrate that is equally suitable for growing semiconductor layers based on a phosphide and an arsenide compound semiconductor material system. Here and in the following, embodiments are described in which phosphide compound semiconductor materials are used. Alternatively, it can be possible to use corresponding arsenide compound semiconductor materials instead of the described phosphide compound semiconductor materials.

A first cladding layer 11 and an active layer 10, each based on a phosphide compound semiconductor material system, are grown on the growth substrate 2. The active layer 10 can be embodied as indicated, for example as a multiple quantum well structure. Alternatively, a single quantum well structure, a pn-junction or a double heterostructure are possible. While the active layer 10 in the embodiment shown comprises InAlGaP with a band gap of about 1.9 eV or more, the first cladding layer 11 comprises InAlP with a larger band gap, in particular with a band gap of about 2.36 eV.

As shown in FIG. 1B, a second cladding layer 12, based on a II-VI compound semiconductor material system, is grown on the active layer 10. The material of the second cladding layer 12 is selected in such a way that the second cladding layer 12, which is grown directly on the active layer 10, has a larger band gap than the active layer 10 and can also be grown on it in a lattice-matched manner. Furthermore, the material of the second cladding layer 12 is adapted to a desired excitation light wavelength with regard to its transmission properties.

For example, in the case of green excitation light with a wavelength of, for example, 525 nm, the second cladding layer 12 can preferably comprise or be made of ZnSe with a band gap of 2.71 eV or particularly preferably ZnS_{0.08}Se_{0.92} with a band gap of greater than or equal to 2.71 eV. In the case of blue excitation light with a wavelength of 450 nm, for example, the material of the second cladding layer can preferably be ZnMgSSe with a band gap of greater than or equal to 2.9 eV. Alternatively, tension-stressed ZnSₓSe₁₋ₓ can be used as material for the second cladding layer.

In comparison to phosphide compound semiconductor materials, the use of a II-VI compound semiconductor material for the second cladding layer allows larger band gaps and thus higher light transmission and improved confinement of charge carriers. By lattice-matched growth it can be possible to create a defect free interface between III-V and II-VI compound semiconductor materials, thus eliminating the risk of charge carrier recombination at this interface. The second cladding layer 12 is grown as the last layer of the semiconductor layer sequence 1, so that contamination between the different compound semiconductor material systems can be avoided. Thus, the cladding layer 12 forms a window layer which completes the semiconductor layer sequence 1.

In particular when using a GaAs growth substrate 2 as described above, it can be advantageous if the growth substrate is thinned or preferably completely removed after the semiconductor layer sequence 1 has been produced, as indicated in FIG. 1C, since GaAs can be opaque especially for light that can be generated by an active layer based on a phosphide compound semiconductor material system.

FIGS. 2A and 2B show further embodiments of epitaxial wavelength conversion elements 100, which can be manufactured according to the method described above. In contrast to the wavelength conversion element 100 of the previous embodiment, the wavelength conversion element of the embodiment in FIG. 2A has a third cladding layer 13 between the active layer 10 and the second cladding layer 12. Like the first cladding layer 11, this one is based on a phosphide compound semiconductor material system and can, in particular, have the same material as the first cladding layer 11. Due to the smaller band gap and the resulting lower transparency of this material compared to the material of the second cladding layer 12, it can be advantageous if the third cladding layer 13 is thin, in particular with a thickness greater than or equal to 5 nm and less than or equal to 100 nm.

The epitaxial wavelength conversion element 100 of the embodiment of FIG. 2B shows a roughening 14 on the side of the first cladding layer 11 facing away from the active layer 10. This can be particularly advantageous with regard to light outcoupling and comprise structure sizes, for example, in the range of 200 nm to 1 μm. The roughening 14 can be produced, for example, as part of the delamination process to remove the growth substrate or subsequently to it.

In connection with FIGS. 3A to 3C, a method for manufacturing a light-emitting semiconductor device 200 with an epitaxial wavelength conversion element 100 is described. The wavelength conversion element 100 is embodied purely exemplary according to the embodiment in FIGS. 1A to 1C. Alternatively, the wavelength conversion element 100 can also have features of the other embodiments described above.

To manufacture the light-emitting semiconductor device 200, as shown in FIG. 3A, a previously provided light-emitting semiconductor chip 4 is attached via a connection layer 3 to the second cladding layer 12 of the semiconductor layer sequence 1 grown on the growth substrate 2. In particular, the method step shown in FIG. 3A can be carried out between the method steps shown in FIGS. 1B and 1C, i.e., before the growth substrate is detached 2. The light-emitting semiconductor chip 4, which has a light-outcoupling surface 41, can be any light-emitting diode chip capable of emitting light at a suitable excitation wavelength. In particular, the method step shown can be carried out in a wafer compound. This means that a semiconductor wafer is provided with a large number of regions corresponding to light-emitting semiconductor chips, while the semiconductor layer sequence 1 is also grown over a large area on the growth substrate 2 which is formed as a substrate wafer. By means of the connection layer 3, the second cladding layer 12 is mounted on the light-outcoupling surface 41, so that the growth substrate 2 is arranged on the side of the semiconductor layer sequence 1 facing away from the light-emitting semiconductor chip 4.

Dielectric organic or inorganic materials are particularly suitable as connection materials for the connection layer 3. For example, a suitable organic connection material can be BCB, while a suitable inorganic connection material can be SiON. Such materials also have a high transparency for the excitation wavelengths to be used.

As shown in FIG. 3B, the process step described in FIG. 1C, namely the removal of the growth substrate 2, is then carried out so that the first cladding layer 11 forms a outcoupling layer of the wavelength conversion element 100 and thus also of the light-emitting semiconductor device 200. A large number of such light-emitting semiconductor devices can be produced by singulation of the aforementioned wafer compound. The light outcoupling during operation of the light-emitting semiconductor device 200 can take place directly or also by means of a lens (not shown) to the surrounding air.

FIG. 3C shows a schematic band diagram for the principal positions of the band gaps of the individual layers of the light-emitting semiconductor device 200 shown in FIG. 3B, wherein in FIGS. 3B and 3C the growth direction 91 of the semiconductor layer sequence 1 and the light emission direction 92 during operation of the light-emitting semiconductor device 200 are indicated. Furthermore, both figures show the interfaces B, T of the wavelength conversion element 100, through which the light is injected (B) and coupled out (T) and at which surface charge carrier recombinations can take place. In addition, the individual layers of the light-emitting semiconductor device 200 in FIG. 3B and the band regions in FIG. 3C are marked with the same Roman numerals for improved allocation. Here, in region III, the band gap of the second cladding layer 12 is marked with the solid line, while the dotted line indicates a band gap that would have a cladding layer based on a phosphide compound semiconductor material corresponding to the first cladding layer 11. Due to the larger band gap of the II-VI compound semiconductor material of the second cladding layer, both a higher transparency for the excitation light emitted by the light-emitting semiconductor chip 4 and an improved confinement of charge carrier pairs can be achieved so that the number of electron-hole pairs generated in the active layer 10 during operation can be increased. Thus, the efficiency of the wavelength conversion element 100 can be improved compared to conventional epi converters based exclusively on III-V compound semiconductor materials.

FIG. 4 shows a method step corresponding to the method step of FIG. 3A according to a further embodiment, in which the second cladding layer 12 is mounted directly on the light-outcoupling surface 41 of the light-emitting semiconductor chip 4 without a connection layer. This can be achieved in particular by a direct wafer bonding process.

The features and embodiments described in connection with the figures can also be combined with one another according to further embodiments, even if not all such combinations are explicitly described. Furthermore, the embodiments described in connection with the figures alternatively or additionally can have further features according to the description in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

### REFERENCE LIST

1 semiconductor layer sequence
2 growth substrate
3 connection layer
4 light-emitting semiconductor chip
10 active layer
11 first cladding layer
12 second cladding layer
13 third cladding layer
14 roughening
41 light-outcoupling surface
91 growth direction
92 light emission direction
100 epitaxial wavelength conversion element
200 light-emitting semiconductor device

1. An epitaxial wavelength conversion element, comprising a semiconductor layer sequence having an active layer arranged between a first cladding layer and a second cladding layer and adapted to absorb light in a first wavelength range and to re-emit light in a second wavelength range different from the first wavelength range,
wherein the first cladding layer and the active layer are based on a III-V compound semiconductor material system,
wherein the second cladding layer is based on a II-VI compound semiconductor material system,
and wherein the second cladding layer is directly adjacent to the active layer.

2. The epitaxial wavelength conversion element according to claim 1, wherein the second cladding layer is a window layer completing the semiconductor layer sequence.

3. The epitaxial wavelength conversion element according to claim 1, wherein the first cladding layer has a roughening on a side remote from the active layer.

4. (canceled)

5. The epitaxial wavelength conversion element according to claim 1, wherein a third cladding layer based on a III-V compound semiconductor material system is arranged between the second cladding layer and the active layer.

6. The epitaxial wavelength conversion element according to claim 1, wherein the III-V compound semiconductor material system is a phosphide and/or arsenide compound semiconductor material system.

7. The epitaxial wavelength conversion element according to claim 1, wherein the active layer is based on InAlGaP and the first cladding layer is based on InAlP.

8. The epitaxial wavelength conversion element according to claim 1, wherein the active layer and the first cladding layer are based on AlGaAs.

9. The epitaxial wavelength conversion element according to claim 1, wherein the second cladding layer comprises one or more Group II elements selected from Mg and Zn and one or more Group VI elements selected from S and Se.

10. A method for manufacturing the epitaxial wavelength conversion element of claim 1, the method comprising the steps:
A) growing a first cladding layer and above it an active layer on a growth substrate, the first cladding layer and the active layer being based on a III-V compound semiconductor material system,
B) growing a second cladding layer on the active layer, the second cladding layer being based on a II-VI compound semiconductor material system, and
C) detaching the growth substrate.

11. The method according to claim 10, wherein the second cladding layer is grown as final layer.

12. A light-emitting semiconductor device, comprising
a light-emitting semiconductor chip having a light-outcoupling surface, and
an epitaxial wavelength conversion element comprising,
a semiconductor layer sequence having an active layer arranged between a first cladding layer and a second cladding layer and adapted to absorb light in a first wavelength range and to re-emit light in a second wavelength range different from the first wavelength range,
wherein the first cladding layer and the active layer are based on a III-V compound semiconductor material system,
wherein the second cladding layer is based on a II-VI compound semiconductor material system, and
wherein the epitaxial wavelength conversion element is arranged with the second cladding layer on the light-outcoupling surface.

13. The semiconductor device according to claim 12, wherein a connection layer comprising a dielectric material is arranged between the light-outcoupling surface and the second cladding layer.

14. The semiconductor device according to claim 12, wherein the second cladding layer is arranged directly on the light-outcoupling surface.

15. A method for manufacturing a light-emitting semiconductor device comprising:
providing a light-emitting semiconductor chip having a light-outcoupling surface is provided,
forming an epitaxial wavelength conversion element by A) growing a first cladding layer and above it an active layer on a growth substrate, the first cladding layer and the active layer being based on a III-V compound semiconductor material system, B) growing a second cladding layer on the active layer, the second cladding layer being based on a II-VI compound semiconductor material system, and C) detaching the growth substrate, and
mounting, between process steps B and C, the semiconductor layer sequence of the epitaxial wavelength conversion element with the second cladding layer on the light-outcoupling surface of the light-emitting semiconductor chip.
